(19) United States
(12) Patent Application Publication
(10) Pub. No.: US 2007/0128823 A1
(43) Pub. Date: Jun. 7, 2007

(54) Method of fabricating semiconductor integrated circuit device

(75) Inventors: Ji-young Lee, Yongin-si (KR); Sang-gyun Woo, Yongin-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/634,142

(22) Filed: Dec. 6, 2006

(30) Foreign Application Priority Data
Dec. 7, 2005 (KR) 10-2005-0118935

(51) Int. Cl. H01L 21/20

(52) U.S. Cl. 438/396

(57) ABSTRACT

A method of fabricating a semiconductor integrated circuit device is disclosed. The method may include forming an etching target layer on a semiconductor substrate, forming a sacrificial mold layer on the etching target layer, forming a photoresist pattern of a first image on the sacrificial mold layer, patterning the sacrificial mold layer using the photoresist pattern of the first image as an etching mask to form sacrificial molds, removing the photoresist pattern of the first image, forming a mask which fills portions between the sacrificial molds and may be an inverse image of the first image and etching the sacrificial molds and the etching target layer using the mask as the etching mask.

### PRIORITY STATEMENT

This application claims priority under 35 USC § 119 to Korean Patent Application No. 10-2005-118935, filed on Dec. 7, 2005, in the Korean Intellectual Property Office (KIPO), the entire contents of which are incorporated herein by reference.

### BACKGROUND

1. Field

Example embodiments relate to a method of fabricating a semiconductor integrated circuit device. Other example embodiments relate to a semiconductor integrated circuit device which is capable of improving the productivity, and a method of fabricating the same.

2. Description of the Related Art

In order to pattern wiring lines and/or contacts of a semiconductor integrated circuit device, a conductive layer and/or an insulating layer may be patterned by forming a photoresist (PR) pattern by a photolithography process. In order to sufficiently utilize a photoresist pattern as an etching mask during an etching process, the photoresist pattern may have an improved etching resistance.

As the design rule of the wiring lines decreases to a deep sub-micron level due to the higher integration of the semiconductor integrated circuit device, there may be cases where the thickness of an etching target layer may not be less than several thousand to tens of thousands of Å. However, the current photoresist may not have the sufficient etching resistance capable of enduring the etching of the etched target layer having the thickness of not less than several thousands to tens of thousands of Å. A method of increasing the height of the photoresist patterns may be used, but a number of photoresists may not have the property capable of forming the photoresist patterns having the desired height. Even though the photoresists are capable of forming the photoresist patterns having the desired height, if the width of the photoresist patterns is narrower, and the height of the photoresist patterns is greater, the photoresist patterns may collapse.

The patterning may be performed by a hard mask as well as by photoresist patterns. After forming the hard mask by using the photoresist patterns as the etching mask, the photoresist patterns may be removed and lower patterns may be formed by using the hard mask as a main etching mask. However, in photoresist patterns, because the formable height is limited, the formable height of the hard mask may also be limited. The desired etching resistance may not be acquired by only the single layer hard mask. The process may become complicated owing to forming the multilayer hard mask.

### SUMMARY

Example embodiments provide a method of fabricating a semiconductor integrated circuit device of which the productivity is improved. Example embodiments are not limited to those mentioned above, and example embodiments will be understood by those skilled in the art through the following description.

A method of fabricating a semiconductor integrated circuit device according to example embodiments may include forming an etching target layer on a semiconductor substrate, forming a sacrificial mold layer on the etching target layer, forming a photoresist pattern of a first image on the sacrificial mold layer, patterning the sacrificial mold layer using the photoresist pattern of the first image as an etching mask to form sacrificial molds, removing the photoresist pattern of the first image, forming a mask which fills portions between the sacrificial molds and may be an inverse image of the first image and etching the sacrificial molds and the etching target layer using the mask as the etching mask.

A method of fabricating a semiconductor integrated circuit device according to example embodiments may include forming an etching target layer on a semiconductor substrate, forming a photoresist pattern of a first image on the etching target layer, patterning an upper part of the etching target layer by using the photoresist pattern as an etching mask to form etching target layer patterns, removing the photoresist pattern of the first image, forming a mask which buries the etching target layer patterns and may be an inverse image of the first image and etching the etching target layer patterns using the mask as the etching mask.

### BRIEF DESCRIPTION OF THE DRAWINGS

Example embodiments will be more clearly understood from the following detailed description taken in conjunction with the accompanying drawings. FIGS. 1-16 represent non-limiting, example embodiments as described herein.

FIG. 1 is a flowchart illustrating a method of fabricating a semiconductor integrated circuit device according to example embodiments;

FIGS. 2 to 8 are diagrams sequentially showing a method of fabricating a semiconductor integrated circuit device according to example embodiments;

FIG. 9 is a flowchart illustrating a method of fabricating a semiconductor integrated circuit device according to example embodiments; and

FIGS. 10 to 16 are diagrams sequentially showing a method of fabricating a semiconductor integrated circuit device according to example embodiments.

### DETAILED DESCRIPTION OF EXAMPLE EMBODIMENTS

Advantages and features of example embodiments and methods of accomplishing the same may be understood more readily by reference to the following detailed description of example embodiments and the accompanying drawings. Example embodiments may, however, be embodied in many different forms and should not be construed as being limited to the embodiments set forth herein. Rather, these embodiments are provided so that this disclosure will be thorough and complete and will fully convey the concept of example embodiments to those skilled in the art, and example embodiments will only be defined by the appended claims. Like reference numerals refer to like elements throughout the specification. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

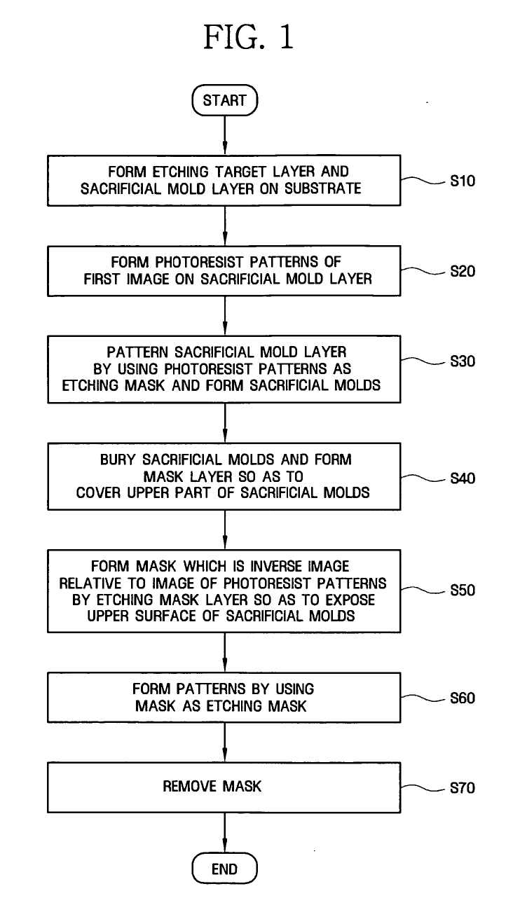

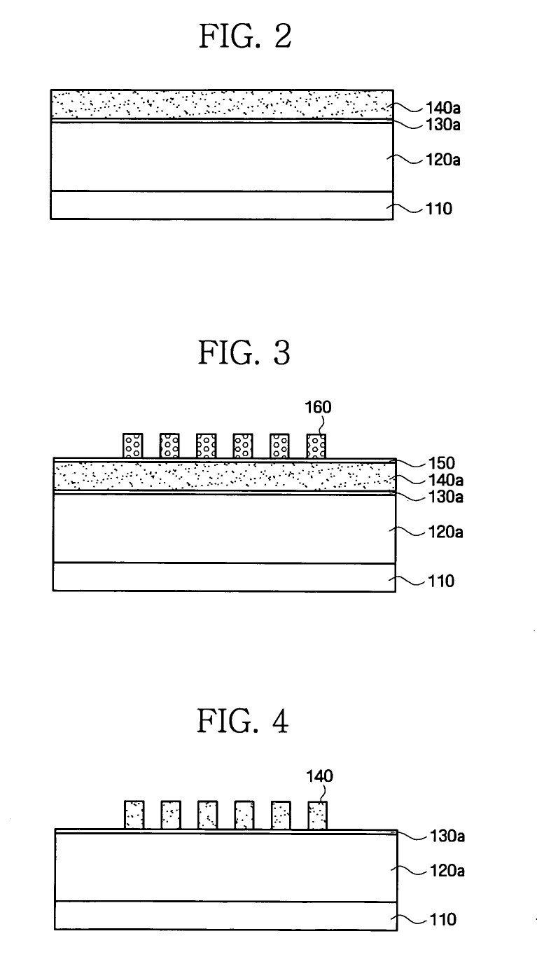

Hereinafter, a method of fabricating a semiconductor integrated circuit device according to example embodiments will be described with reference to FIGS. 1 to 8. FIG. 1 is a flowchart illustrating a method of fabricating a semiconductor integrated circuit device according to example embodiments. FIGS. 2 to 8 are diagrams sequentially showing a method of fabricating a semiconductor integrated circuit device according to example embodiments.

Referring to FIGS. 1 and 2, an etching target layer 120a and a sacrificial mold layer 140a may be formed on a semiconductor substrate 110 (S10). The semiconductor substrate 110 may be, for example, a silicon substrate, a SOI (Silicon On Insulator) substrate, a gallium arsenic substrate, a silicon germanium substrate, a ceramic substrate, a quartz substrate and/or a display-glass substrate. The semiconductor substrate 110 may be a P-type substrate, and a P-type epitaxial layer which is not shown in the drawings may be grown on the semiconductor substrate 110. According to the type of etching target layer 120a, a lower wiring line, a transistor and/or a capacitor may be formed between the semiconductor substrate 110, and the etching target layer 120a.

The etching target layer 120a may be a substance to be patterned, and may vary depending on an object to be formed. For example, when forming an opening pattern forming a storage node and/or a metal contact pattern, the etching target layer 120a may be an oxidation layer (for example, PE-TEOS and/or USG) and an antireflective coating (for example, a nitride layer and/or an oxynitride layer). Further, when forming a recess trench so as to form a RCAT (Recessed Channel Array Transistor), the etching target layer 120a may be a silicon substrate, and when forming various kinds of wiring lines, the etching target layer 120a may be a conductive layer. For example, the oxidation layer may be used as the sacrificial mold layer 140a. An etch stop layer 130a may be also formed between the etching target layer 120a and the sacrificial mold layer 140a. When the sacrificial mold layer 140a is patterned, the etch stop layer 130a may prevent or reduce damage to the etching target layer 120a and may etch to a proper height. The etch stop layer 130a may be formed of, for example, SiON, SiN, and polysilicon.

Referring to FIGS. 1 and 3, a photoresist pattern 160 of a first image may be formed on the sacrificial mold layer 140a (S20). A photoresist layer may be formed on the sacrificial mold layer 140a. A photoresist having resolution suitable for the size of the patterns able to transfer to the etching target layer 120a may be used as the photoresist layer. For example, in forming the patterns, e.g., a metal contact pattern, having the size of about 100 nm or more, a KrF (about 248 nm) photoresist may be used. Furthermore, in forming the opening pattern forming the storage node, the recess trench pattern and/or the wiring line pattern, having the size of about 100 nm or less, for example, an ArF (about 193 nm) photoresist, a F₂ (about 158 nm) photoresist may be used. The antireflective coating 150 may also be formed under the photoresist layer. The antireflective coating 150 may be formed of, for example, an organic antireflective coating (ARC). The photoresist pattern 160 of the first image may be formed by patterning the photoresist layer by means of the photolithography process. The first image, which is an inverse image of fine patterns to be formed, may be formed.

For example, where the patterns to be formed are the contact pattern, the opening pattern forming the storage node and/or the recess trench pattern, the photoresist pattern may be formed so that the contact, the opening and/or the trench may be embossed. Embossing rather than engraving the patterns of the same design rule on the photoresist layer may be easier. This is due to the fact that leaving the photoresist of a narrower region, rather than completely removing the photoresist of the narrower region, may be easier. If the size of the embossed patterns becomes smaller, while embossing the contact pattern, the opening pattern, and the trench pattern having the small design rule on the photoresist, it may be possible to effectively form a smaller contact pattern, opening pattern, and trench pattern.

The photoresist layer (not shown) may be formed of either a positive photoresist and/or a negative photoresist. When using the negative photoresist, an existing mask may be used. If the photolithography process is performed using the negative photoresist, the photoresist pattern which is the inverse image of the mask pattern may be formed. The typical mask may be used in the process of example embodiments.

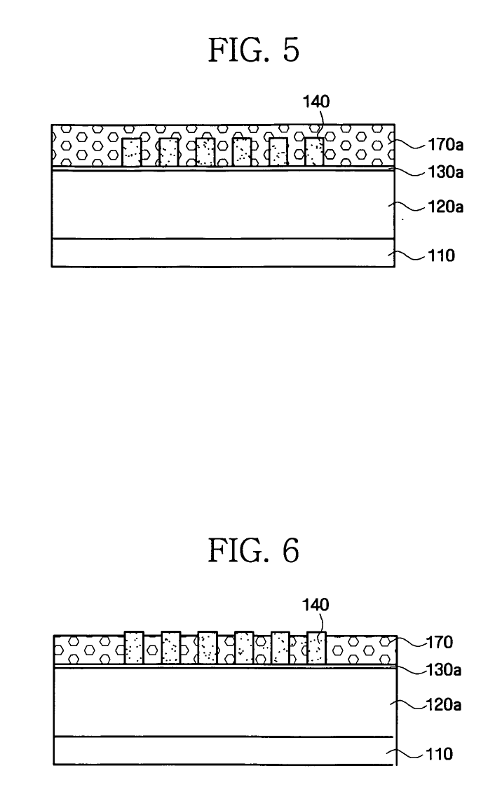

Referring to FIGS. 1 and 4, the sacrificial mold layer (refer to 140a in FIG. 3) may be patterned by using the photoresist patterns (refer to 160 in FIG. 3) as an etching mask, thus forming sacrificial molds 140 (S30). After the sacrificial molds 140 are formed by the etching process, the photoresist pattern 160 and the antireflective coating (refer to 150 in FIG. 3) formed on the sacrificial molds 140 may be removed by an ashing process. Referring to FIGS. 1 and 5, the sacrificial molds 140 may be buried, and a mask layer 170a may be formed to cover the upper part of the sacrificial molds 140 (S40).

The mask layer 170a may be formed of materials having an improved etching resistance. The layer may be formed in a shorter time at the lower temperature and an additional smoothing process may not be required. The mask layer 170a may be formed of, for example, the photoresist and the polymer capable of being formed by a spin-on process. For example, a KrF photoresist and an I-Line photoresist having the improved etching resistance may be used as the photoresist. An ArF photoresist having the improved etching resistance may be used as the photoresist. The polymer may be, for example, a polymethylmethacrylate (PMMA), a polystyrene (PS), and a polyimide having a number of double bonds.

If the mask layer 170a is formed by the spin-on process, the mask layer 170a may be smoothly formed on the indented sacrificial molds 140. If the mask layer 170a is formed of the nitride layer and/or the oxide layer to which the spin-on process is not applied, the indented thin layer may be formed along the profile of the sacrificial molds 140, and, for example, the CMP (chemical mechanical polishing) process may be additionally required. When forming the mask layer 170a by a spin-on process, the process may be simplified.

After the mask layer 170a is coated by the spin-on process, the forming layer may be accomplished by the only curing process that treats by heating at about 300° C. or less. The heat treatment process may be to vaporize water and a solvent inside the mask layer 170a. The nitride layer and/or the oxide layer widely known as the conventional hard mask material may be formed by, for example, the chemical vapor deposition (CVD) process which requires a higher temperature of about 500° C. or more. If the semiconductor integrated circuit device is manufactured at the higher temperature, a heat budget, which has an effect on the performances of the lower structure (for example, transistor and/or wiring line) of the etching target layer 120a, may increase. In contrast, if the mask layer 170a is formed by the spin-on process, the semiconductor integrated circuit device may be formed at a relatively low temperature. The heat budget may be minimized and/or reduced, thereby preventing or reducing damage caused by heat.

While the time for depositing the nitride layer and/or the oxide layer by the CVD process takes at least about one hour, the total time of the coating and heat treatment by the spin-on process takes about 10 minutes. When forming the mask layer 170a by the spin-on process, the mask layer 170a may be formed in a relatively short time, thus improving the productivity. Referring to FIGS. 1 and 6, the mask 170, which is the inverse image relative to the image of the photoresist patterns 160, may be formed by etching the mask layer (refer to 170a in FIG. 5) so as to expose the upper surface of the sacrificial molds 140 (S50). A portion of the mask layer 170a may be etched by, for example, the etch-back process.

If the patterns are formed with the photoresist, the upper part of the photoresist patterns may be circularly formed during a developing process. If the upper part of the photoresist patterns is circularly formed, because the circular part may not be used as the mask 170, the height of the required patterns may be greater. However, if the mask 170 is formed by removing a portion of the mask layer 170a by means of the etch-back process, the profile of the upper surface of the mask 170 may become smooth. The upper surface and the lateral surface of the mask 170 pattern may be vertically formed. If the upper surface and the lateral surface of the mask 170 pattern are vertically formed, the thickness of the mask 170 to be required may be thinner than that of the mask required when the upper part of the mask 170 pattern is circularly formed.

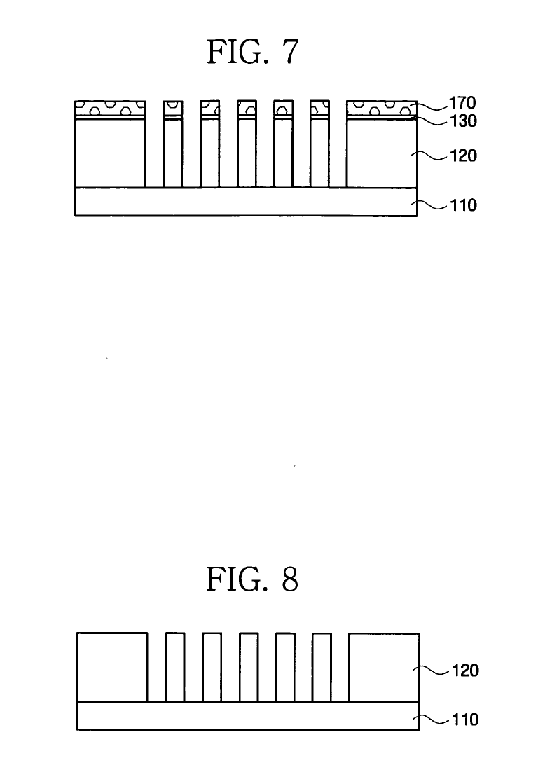

Referring to FIGS. 1 and 7, patterns 120 may be formed by using the mask 170 as the etching mask (S60). The patterns 120 may be formed by etching the sacrificial molds (refer to 140 in FIG. 6) and the etching target layer 120a by using the mask 170 as the etching mask. Because the mask 170 used has materials having the improved etching resistance, the fine patterns having the depth which is deeper than the width to be etched may be sufficiently etched. An etch stop layer 130 may be between the mask 170 and the patterns 120.

Referring to FIGS. 1 and 8, the mask (refer to 170 in FIG. 7) may be removed (S70). The patterns 120 may be accomplished by removing the mask 170 formed on the patterns 120. The method of fabricating the semiconductor integrated circuit device according to example embodiments may include forming the photoresist patterns 160, forming the sacrificial molds 140 by using the photoresist patterns 160, and forming the mask 170 which is the inverse image relative to the image of the photoresist patterns 160 by filling portions between the sacrificial molds 140 via the damascene process. The fine patterns having the higher accuracy profile may be formed. By using materials having the improved etching resistance in the mask 170, the etching process may effectively proceed with higher accuracy.

Because the mask 170 is formed by means of the spin-on process capable of forming the layer for a shorter time at a lower temperature, the process may be simpler and the process time may be reduced. The semiconductor integrated circuit device may prevent or reduce damage caused by heat. Productivity of the semiconductor integrated circuit device may be improved.

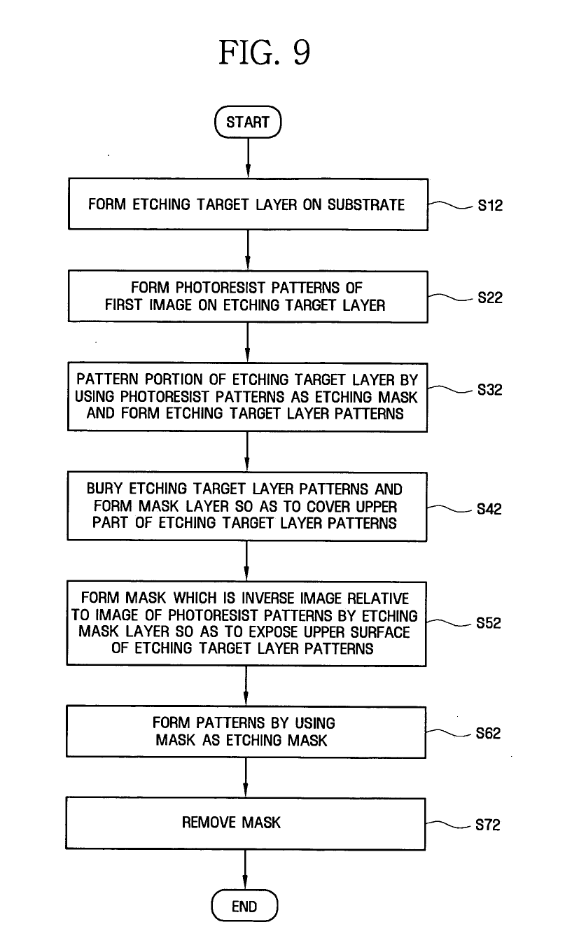

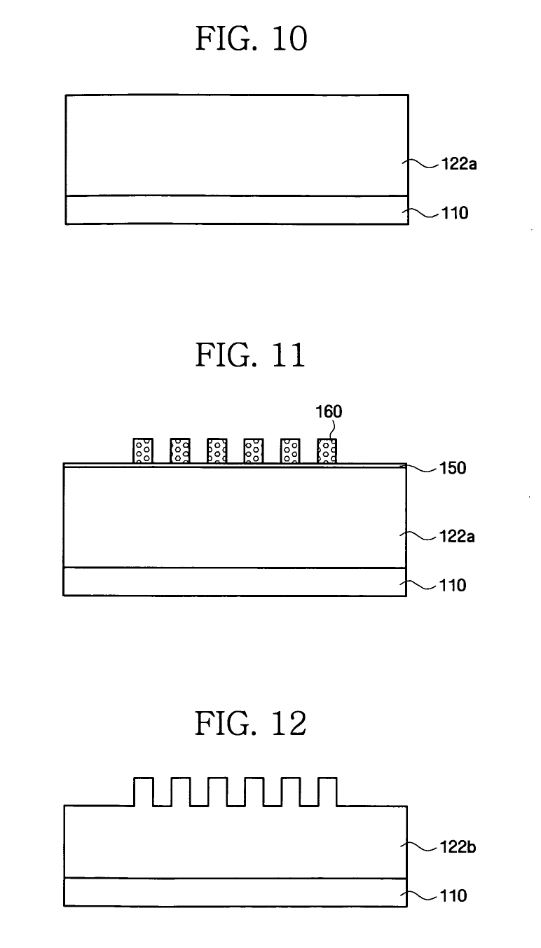

Hereinafter, a method of fabricating a semiconductor integrated circuit device according to example embodiments will be described with reference to FIGS. 9 to 16. FIG. 9 is a flowchart illustrating a method of fabricating a semiconductor integrated circuit device according to example embodiments. FIGS. 10 to 16 are diagrams sequentially showing the method of the fabricating the semiconductor integrated circuit device according to example embodiments. Constituent elements substantially similar to FIGS. 1 to 8 denote like reference numerals, and thus their description thereof will be omitted. The method of fabricating the semiconductor integrated circuit device according to example embodiments differs from the method of fabricating the semiconductor integrated circuit device according to example embodiments in that the sacrificial mold layer (refer to 140a in FIG. 2) may not be used.

Referring to FIGS. 9 and 10, an etching target layer 122a may be formed on a semiconductor substrate 110 (S12). The etching target layer 122a may be a substance to be patterned, and may vary depending on an object to be formed. For example, when forming an opening pattern forming a storage node and/or a metal contact pattern, the etching target layer 122a may be an oxidation layer (for example, PE-TEOS and/or USG) and an antireflective coating (for example, a nitride layer and/or an oxynitride layer). Further, when forming a recess trench so as to form a RCAT (Recessed Channel Array Transistor), the etching target layer 122a may be a silicon substrate, and when forming various kinds of wiring lines, the etching target layer 122a may be a conductive layer.

Referring to FIGS. 9 and 11, photoresist patterns 160 of a first image may be formed on the etching target layer 122a (S22). A photoresist layer may be formed on the etching target layer 122a. A photoresist, having resolution suitable for the size of patterns able to be transferred to the etching target layer 120a, may be used as the photoresist layer.

For example, when forming the patterns, e.g., a metal contact pattern, having the size of about 100 nm or more, a KrF (about 248 nm) photoresist may be used. Furthermore, when forming the opening pattern forming the storage node, the recess trench pattern, and/or the wiring lines pattern having the size of about 100 nm or less, for example, an ArF (about 193 nm) photoresist, a F₂ (about 158 nm) photoresist may be used. The antireflective coating 150 may also be formed under the photoresist layer. The antireflective coating 150 may be formed of, for example, an organic antireflective coating.

The photoresist patterns 160 of the first image may be formed by patterning the photoresist layer by means of a photolithography process. The first image, which is an inverse image of fine patterns to be formed, may be formed. The photoresist layer (not shown) may be formed of either a positive photoresist and/or a negative photoresist.

Referring to FIGS. 9 and 12, a portion of the etching target layer (refer to 122a in FIG. 11) may be patterned by using the photoresist patterns (refer to 160 in FIG. 3) as an etching mask, thus forming etching target layer patterns 122b (S32). After a portion of the etching target layer 122a is patterned by using the photoresist patterns 160 as the etching mask, the etching target layer patterns 122b may be formed, but only the upper part of the etching target layer 122a may be patterned. By controlling the etching time of the etching target layer 122a, a portion of the etching target layer patterns may only be patterned. The height of the etching target layer patterns 122b not being patterned may be equal to and/or greater than the height of the patterns to be finally formed. The photoresist patterns 160 and the antireflective coating (refer to 150 in FIG. 11) formed on the etching target layer patterns 122b may be removed by the ashing process.

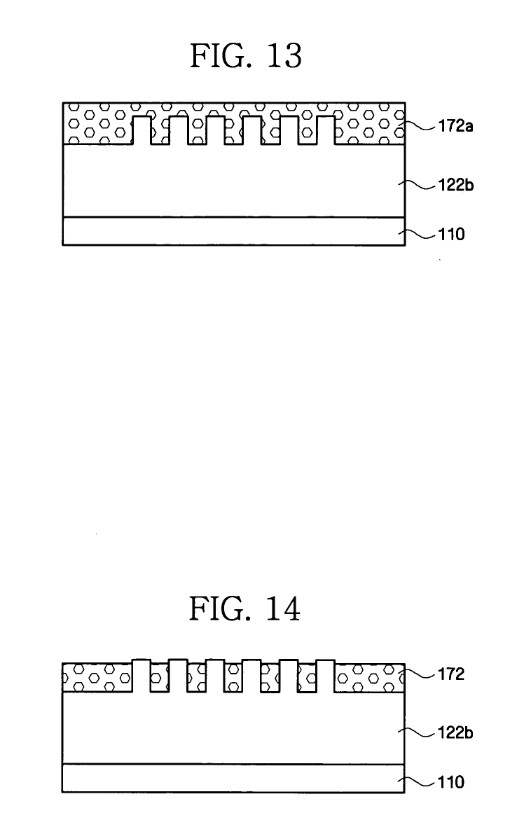

Referring to FIGS. 9 and 13, the etching target layer patterns 122b may be buried, and a mask layer 172a may be formed to cover the upper part of the etching target layer patterns 122b (S42). The mask layer 172a may be formed of materials having an improved etching resistance. The layer may be formed in a shorter time at a lower temperature and an additional smoothing process may not be required. The mask layer 172a may be formed of, for example, the photoresist and the polymer capable of being formed by a spin-on process. A KrF photoresist and an I-Line photoresist having the improved etching resistance may be used as the photoresist. An ArF photoresist having the improved etching resistance may be used as the photoresist. The polymer may be, for example, a polymethylmethacrylate (PMMA), a polystyrene (PS) and/or a polyimide having a number of double bonds. After the mask layer 172a is coated by the spin-on process, the forming layer may be accomplished by the only curing process which treats by heating at about 300° C. or less. The heat treatment process may vaporize water and a solvent inside the mask layer 172a.

Referring to FIGS. 9 and 14, the mask 172, which is the inverse image of the photoresist patterns 160, may be formed by etching the mask layer (refer to 172a in FIG. 13) to expose the upper surface of the etching target layer pattern 122b (S52). A portion of the mask layer 172a may be etched by, for example, the etch-back process.

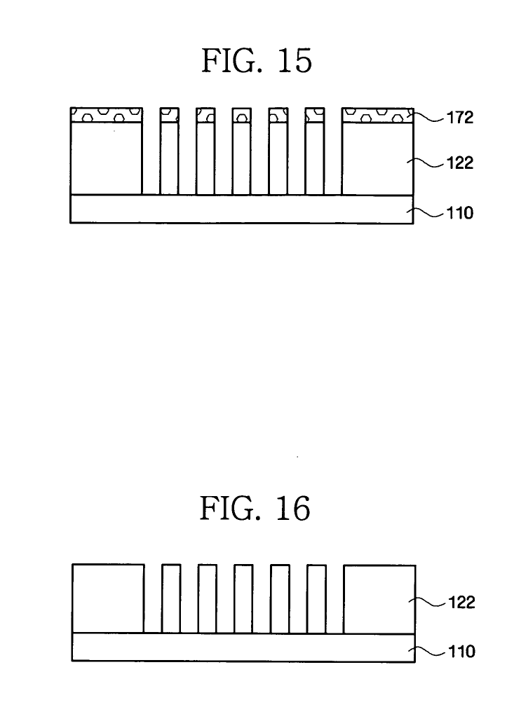

Referring to FIGS. 9 and 15, the patterns 122 may be formed by using the mask 172 as the etching mask (S62). Because the mask 172 has the materials with the improved etching resistance, the fine patterns having the depth, which is deeper than the width to be etched, may be sufficiently etched. Referring to FIGS. 9 and 16, the mask 172 may be removed (S72). The patterns 122 may be accomplished by removing the mask 170 formed on the patterns 122.

By forming the photoresist patterns which are the inverse image of the patterns to be formed, the patterns may be formed with higher accuracy. By using materials having improved etching resistances as masks, the etching process has higher accuracy and may be more effective. The process may be simpler, the process time may be reduced, and the semiconductor integrated circuit device may prevent or reduce damage caused by heat. Example embodiments improve the productivity of the process of producing semiconductor integrated circuit devices.

Although example embodiments have been described in connection with the example embodiments, it will be apparent to those skilled in the art that various modifications and changes may be made thereto without departing from the scope and spirit of example embodiments. Therefore, it should be understood that the above example embodiments are illustrative, but not limitative. As described above, according to the semiconductor integrated circuit device and the method of fabricating the same, at least one of the following effects may be obtained.

What is claimed is:

1. A method of fabricating a semiconductor integrated circuit device, the method comprising:
forming an etching target layer on a semiconductor substrate;
forming a sacrificial mold layer on the etching target layer;
forming a photoresist pattern of a first image on the sacrificial mold layer;
patterning the sacrificial mold layer using the photoresist pattern of the first image as an etching mask to form sacrificial molds;
removing the photoresist pattern of the first image;
forming a mask which fills portions between the sacrificial molds and is an inverse image of the first image; and
etching the sacrificial molds and the etching target layer using the mask as the etching mask.

2. The method of claim 1, wherein forming the mask includes forming the mask by spin-on coating.

3. The method of claim 1, wherein forming the mask includes forming the mask at a temperature of about 300° C. or less.

4. The method of claim 1, wherein forming the mask includes forming the mask of a photoresist or a polymer.

5. The method of claim 1, wherein forming the mask includes forming a mask layer that fills portions between the sacrificial molds, and etching the mask layer to expose upper surfaces of the sacrificial molds.

6. The method of claim 1, further comprising:
forming an etch stop layer on the etching target layer, wherein the etch stop layer is etched simultaneously with the sacrificial molds and the etching target layer by the mask as the etching mask.

7. The method of claim 1, wherein a contact pattern, an opening pattern for forming a storage pattern, or a recess trench pattern is formed on the etching target layer, and the photoresist pattern is formed such that the contact pattern, the opening pattern, or the recess trench pattern is embossed.

8. The method of claim 1, wherein forming the photoresist pattern includes forming a negative photoresist.

9. A method of fabricating a semiconductor integrated circuit device, the method comprising:
forming an etching target layer on a semiconductor substrate;
forming a photoresist pattern of a first image on the etching target layer;
patterning an upper part of the etching target layer by using the photoresist pattern as an etching mask to form etching target layer patterns;
removing the photoresist pattern of the first image;
forming a mask which buries the etching target layer patterns and is an inverse image of the first image; and
etching the etching target layer patterns using the mask as the etching mask.

10. The method of claim 9, wherein forming the mask includes forming the mask by spin-on coating.

11. The method of claim 9, wherein forming the mask includes forming the mask at a temperature of about 300° C. or less.

12. The method of claim 9, wherein forming the mask includes forming the mask of a photoresist or a polymer.

13. The method of claim 9, wherein forming the mask includes forming a mask layer which fills portions between the etching target layer patterns, and etching the mask layer so as to expose upper surfaces of the etching target layer patterns.

14. The method of claim 9, wherein a contact pattern, an opening pattern for forming a storage pattern, or a recess trench pattern is formed on the etching target layer, and the photoresist pattern is formed such that the contact pattern, the opening pattern, or the recess trench pattern is embossed.

15. The method of claim 9, wherein forming the photoresist pattern includes forming the photoresist pattern of a negative photoresist.
